(19) United States
(12) Patent Application Publication
(10) Pub. No.: US 2009/0310291 A1
(43) Pub. Date: Dec. 17, 2009

(54) WORKSTATION MODESTY PANEL WITH LAPTOP STORAGE AND DOCKING

(75) Inventors: Terry Z. Willburn, Tonganoxie, KS (US); Jillian Pai, Chicago, IL (US); Sean Scott, Chicago, IL (US); Dawn M. Boileau, Liberty, MO (US); Vicky McCollum, Kansas City, MO (US)

Correspondence Address: HOVEY WILLIAMS LLP, 10801 Mastin Blvd., Suite 1000, Overland Park, KS, 66210, US

(73) Assignee: SURFACE TECHNOLOGIES, INC., Kansas City, MO (US)

(21) Appl. No.: 12/137,292

(22) Filed: Jun. 11, 2008

(51) Int. Cl. H05K 5/00; A47B 81/00

(52) U.S. Cl. 361/679.22; 312/223.2

(57) ABSTRACT

A workstation configured to provide laptop storage and permit docking of the laptop broadly includes a desk and a modesty panel attached to the desk. The modesty panel includes a chassis and a panel door swingably attached to the chassis into and out of a closed position where the chassis and panel door define an enclosed space. The chassis includes power and data terminals for providing electrical power and data access to the laptop. The chassis further includes a removable partition with containers for holding the laptop and peripherals within the chassis. With the panel door closed, the chassis and panel door cooperatively define a passage that is configured to receive a transmission cable for interconnecting terminals and the laptop. The modesty panel is configured to securely store the laptop in the enclosed space by restricting removal of the laptop when the panel door is closed. The modesty panel is also configured to serve as a docking station when the panel door is closed and the laptop is removed from the enclosed space by permitting the transmission cable to extend into and out of the enclosed space by extending through the passage.

### CROSS-REFERENCE TO RELATED APPLICATION

This application is being filed contemporaneously with application for U.S. Design Pat. Ser. No. ______, entitled WORKSTATION, which is hereby incorporated in its entirety by reference herein.

### BACKGROUND

1. Field

The present invention relates generally to desks and workstations. More specifically, embodiments of the present invention concern a workstation including a modesty panel that provides laptop storage and permits docking of the laptop.

2. Discussion of Prior Art

Conventional desks and tables are often configured as a workstation for use with laptops or other computers. For instance, elementary schools provide computer instruction to students by supplying each student with a laptop for a particular lesson or examination. Laptops are typically brought into the classroom from a secure storage room using a cart designed to carry a large number of laptops. The laptops are placed in the classroom, with power being provided by power outlets throughout the classroom, and with server and internet access provided by data jacks in the classroom or by wireless connection to a wireless router. Prior art computer workstations have a number of power outlets to provide power to the computer and other computer peripherals, such as a printer. It is also known in the art to secure a computer to a workstation by using a cable that is locked to the computer and prevents theft of the computer.

Prior art desks and workstations are problematic and suffer from various undesirable limitations. For instance, prior art desks do not provide storage that adequately prevents tampering and theft of equipment such as laptops and peripherals. Prior art desks also fail to provide storage that provides convenient access to stored equipment. Furthermore, prior art desks fail to provide convenient and secure access to power and data.

### SUMMARY

The present invention provides a workstation that does not suffer from the problems and limitations of the prior art desks and workstations set forth above.

A first aspect of the present invention concerns a workstation modesty panel configured to be attached to a desk below a desktop. The workstation modesty panel is operable to store a laptop computer in a storage condition and operable to be coupled to the laptop computer in an operating condition where the desktop supports the laptop computer for use. The workstation modesty panel broadly includes a chassis, a panel door, and an electrical terminal. The chassis presents a laptop access opening through which the laptop computer is configured to pass when placed in or removed from storage. The panel door is shiftably attached to the chassis and shiftable into and out of a covering position where the panel door substantially covers the laptop access opening. The chassis and panel door cooperatively define a storage space operable to receive the laptop computer in the storage condition. The panel door is in the covering position when the workstation modesty panel is in the storage condition, with the chassis and panel door operable to cooperatively restrict removal of the laptop computer from the storage space. The panel door is shiftable out of the covering position to permit removal of the laptop computer from the storage space via the laptop access opening. The electrical terminal is mounted within the storage space and is configured to be operably coupled to the laptop computer by a transmission wire. At least one of the chassis and the panel door presents a wire passage adjacent the laptop access opening that permits the transmission wire to extend from the terminal to the laptop computer in the operating condition, when the panel door is in the covering position.

A second aspect of the present invention concerns a laptop workstation configured to store and operably support a laptop computer. The laptop workstation broadly includes a desk and a panel assembly. The desk includes a desktop that presents proximal and distal margins and a laterally-extending work surface extending between the margins. The desk defines an open space below the desktop that is operable to receive an operator's legs extending under the proximal margin from a location outside the open space. The desktop presents a laterally-extending work surface configured to support the laptop computer thereon for use in an operating condition. The panel assembly is operable to store the laptop computer in a storage condition and operable to be coupled to the laptop computer in the operating condition. The panel assembly is attached to the desk and extends along the distal margin below the desktop to at least partly conceal the open space and thereby provide a modesty panel. The panel assembly includes a chassis presenting a laptop access opening through which the laptop computer is configured to pass when placed in or removed from storage. The panel assembly includes a panel door shiftably attached to the chassis and shiftable into and out of a covering position where the panel door substantially covers the laptop access opening. The chassis and panel door cooperatively define a storage space configured to store the laptop computer in the storage condition. The panel door is in the covering position when the panel assembly is in the storage condition, with the chassis and panel door operable to cooperatively restrict removal of the laptop computer from the storage space. The panel door is shiftable out of the covering position to permit removal of the laptop computer from the storage space via the laptop access opening. The panel assembly includes an electrical terminal mounted within the storage space and is configured to be operably coupled to the laptop computer by a transmission wire. At least one of the chassis and the panel door presents a wire passage adjacent the laptop access opening that permits the transmission wire to extend from the terminal to the laptop computer in the operating condition, when the panel door is in the covering position.

Other aspects and advantages of the present invention will be apparent from the following detailed description of the preferred embodiments and the accompanying drawing figures.

### BRIEF DESCRIPTION OF THE DRAWING FIGURES

Preferred embodiments of the invention are described in detail below with reference to the attached drawing figures, wherein:

FIG. 1 is a left front perspective view of a workstation constructed in accordance with a first preferred embodiment of the present invention;

FIG. 2 is a right front perspective view of the workstation shown in FIG. 1;

FIG. 3 is a right front perspective view of the workstation shown in FIGS. 1 and 2, showing a desk supporting a laptop thereon and a modesty panel attached to the desk, with the modesty panel including a chassis and a door being in a closed position relative to the chassis, and with cables extending from the laptop into the modesty panel;

FIG. 4 is a fragmentary partly exploded perspective view of the workstation shown in FIGS. 1-3, showing the door in an open position and a removable wall of the modesty panel exploded therefrom to show power and data terminals for connection to the laptop;

FIG. 5 is a fragmentary cross-sectional view of the workstation shown in FIGS. 1-4, showing the door in the closed position and locked in the closed position by a lock;

FIG. 6 is a fragmentary cross-sectional view of the workstation shown in FIGS. 1-5, showing a damper that interconnects the door and the chassis, and also showing a passage between the door and chassis with one of the cables extending through the passage;

FIG. 7 is a left front perspective view of a workstation constructed in accordance with a second preferred embodiment of the present invention, showing a pair of modesty panel doors in an open position; and

FIG. 8 is a right front perspective view of the workstation shown in FIG. 7, showing multiple workstations positioned side-by-side, with the modesty panels of the workstations having a punch-out section removed to permit transmission wires to extend between the modesty panels.

The drawing figures do not limit the present invention to the specific embodiments disclosed and described herein. The drawings are not necessarily to scale, emphasis instead being placed upon clearly illustrating the principles of the preferred embodiment.

### DETAILED DESCRIPTION OF THE PREFERRED EMBODIMENTS

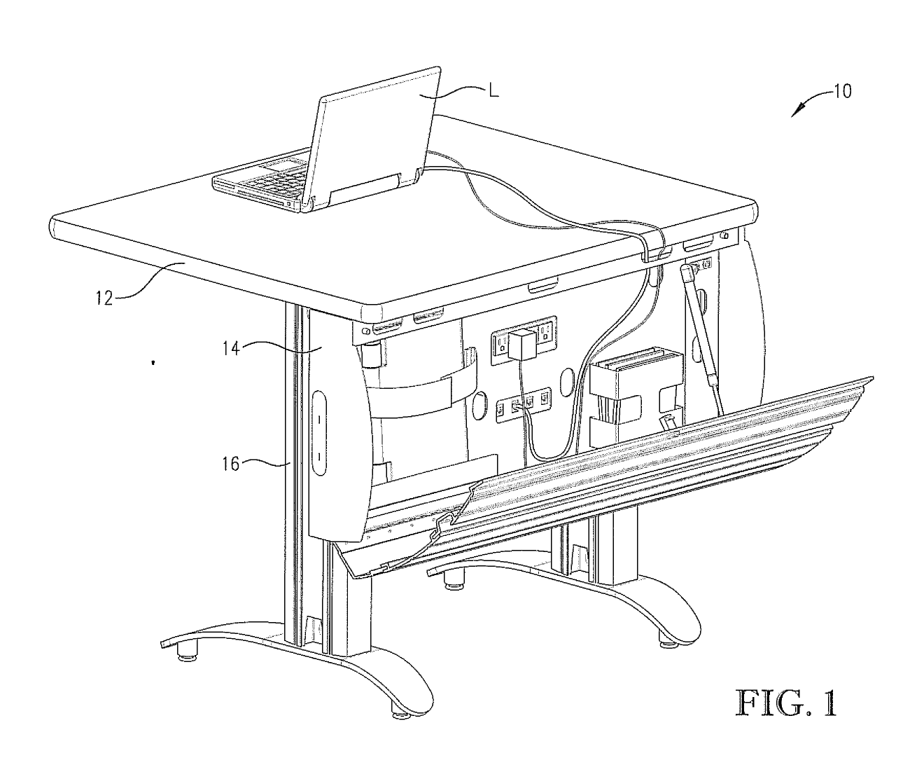

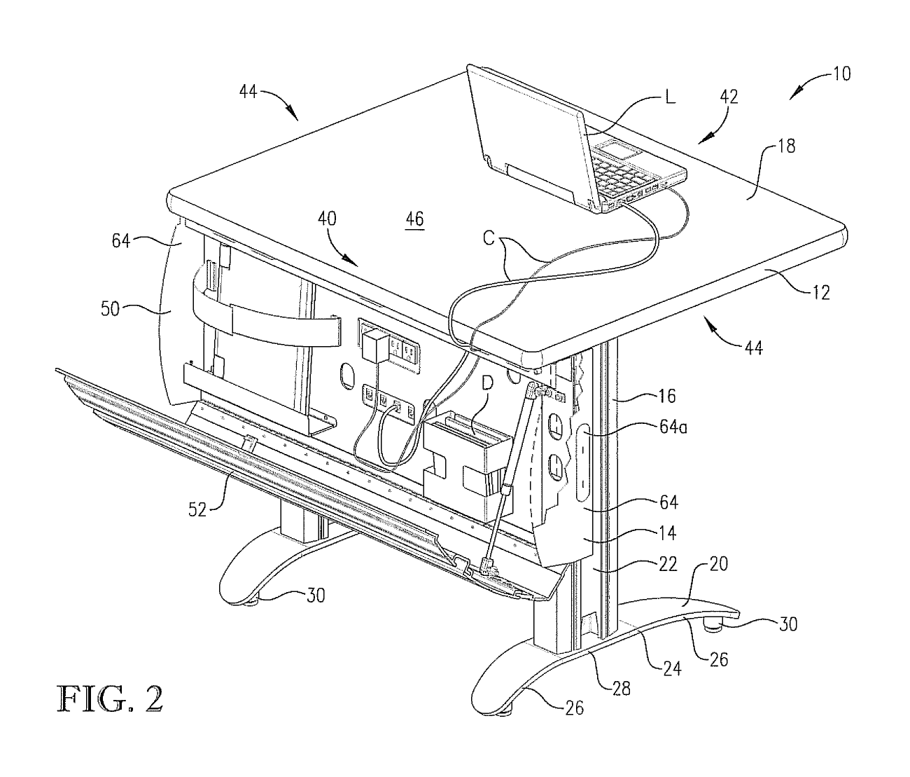

Turning initially to FIGS. 1 and 2, a workstation 10 serves to support a laptop computer L during laptop operation and also serves to provide a source of data and power to the laptop computer L. The workstation 10 also serves to securely contain the laptop computer L for storage purposes. The illustrated workstation 10 is preferably configured for providing a laptop workstation with dedicated support and storage of the laptop computer L, but it is also within the ambit of the present invention where the workstation 10 is used for other work-related purposes or for entertainment purposes. For instance, the workstation 10 could also be configured to securely store items such as a monitor, flat-screen television, DVD video player, projector, printer, books, magazines, or office supplies. The workstation 10 broadly includes a desk 12 and a modesty panel 14.

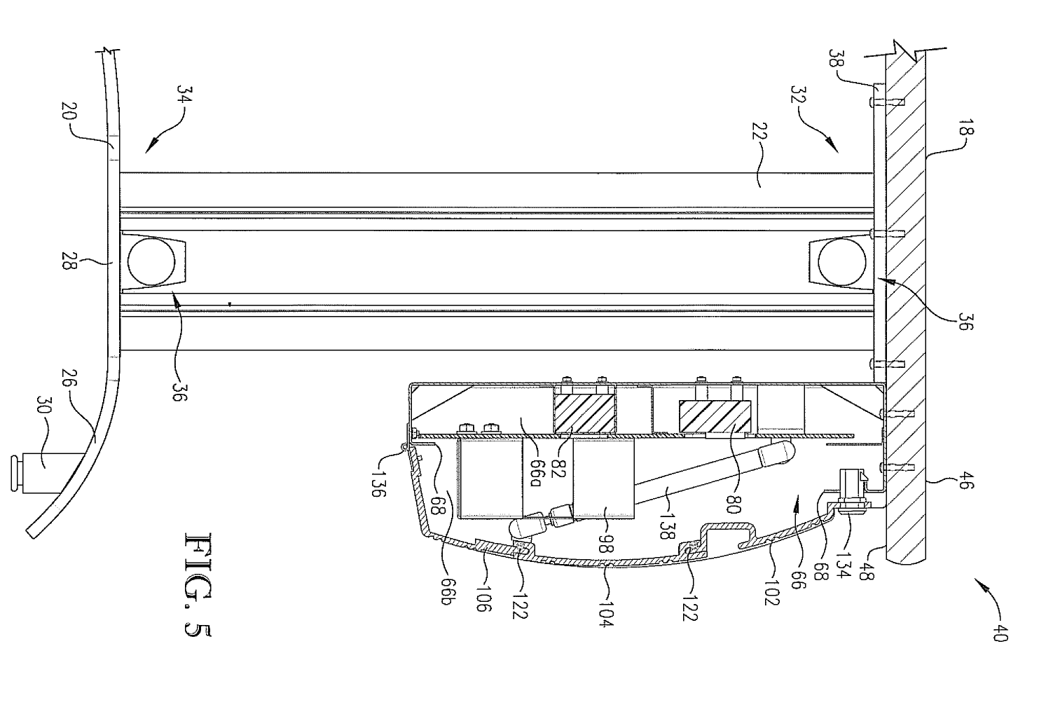

Turning to FIGS. 2 and 5, the desk 12 broadly includes a base 16 and a desktop 18 supported by the base 16. In the usual manner, the base 16 includes a pair of spaced apart legs, with each leg including a pedestal 20 and an upright post 22. The pedestal 20 includes a laterally-extending elongated body 24 with arcuate end sections 26 and an intermediate section 28 that interconnects the end sections 26. The pedestal 20 also includes cylindrical glides 30 attached to respective end sections 26. The upright post 22 is elongated and presents upper and lower post ends 32,34, with openings 36 formed adjacent to each post end 32,34. The upright post 22 is secured to the pedestal 20 by attaching the lower post end 34 to the intermediate section 28 of the body 24. The leg also includes a flange 38 attached to the upper post end 32 for attaching the leg to the desktop 18.

The desktop 18 is unitary and substantially flat, with a rectangular outline that presents front and rear margins 40,42 and side margins 44. The desktop 18 also presents an upper work surface 46 and a lower surface 48. Each leg is attached to the desktop 18 by attaching the flange 38 to the lower surface 48 adjacent a respective side margin 44 with threaded fasteners, with the posts 22 being spaced closer to the front margin 40 than the rear margin 42. In the usual manner, the base 16 and desktop 18 cooperatively form an open space beneath the lower surface 48 that permits a user to be seated adjacent the rear margin 42, with room for the user's legs to extend and move beneath the lower surface 48.

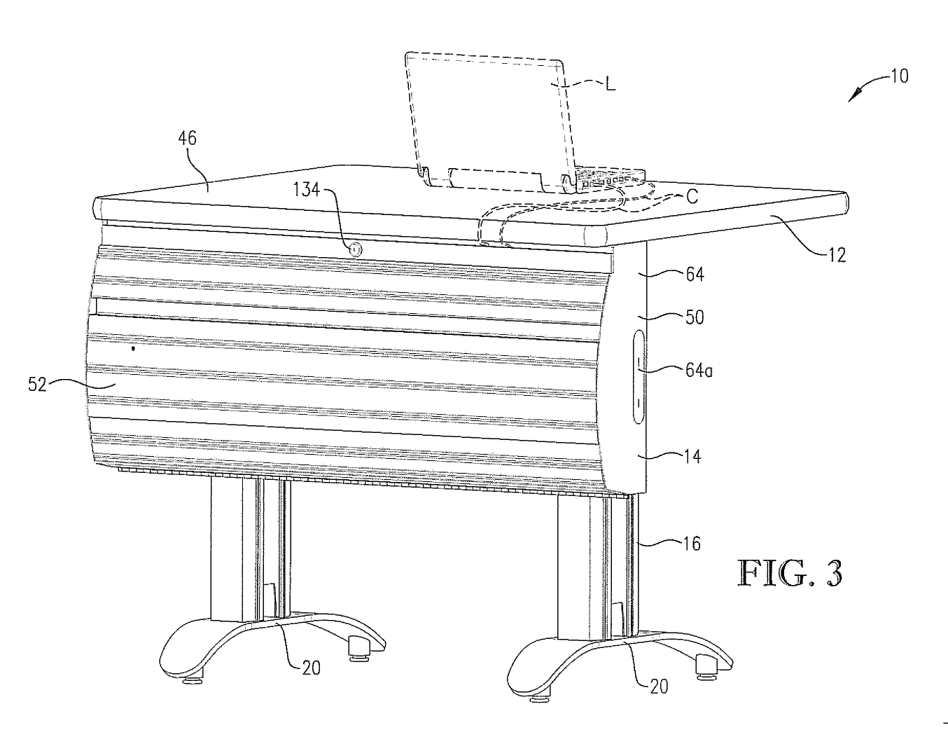

Turning to FIGS. 2-6, the modesty panel 14 is attached to the desk 12 to provide dedicated storage and sources of power and data to the desk 12 as will be discussed further. While the illustrated workstation 10 includes a single modesty panel 14, it is within the ambit of the present invention where multiple modesty panels 14 are attached to the desk 12. The modesty panel 14 broadly includes a chassis 50 and a panel door 52 swingably attached to the chassis 50. The chassis 50 preferably includes a chassis shell with a rear wall 54, top and bottom walls 56,58, top and bottom flanges 60,62, and side walls 64. The rear wall 54 presents a plurality of oval-shaped holes that permit transmission wires to extend through the rear wall 54. The side walls 64 each include a punch-out 64a that is formed by a line of weakness in the side wall 64 and the punch-out 64a is selectively removable so that the side wall 64 presents an oval-shaped hole that permits wires to extend through the side wall 64. The walls 54,56,58,64 preferably include the illustrated arrangement of holes to permit transmission wires to extend into and out of the chassis 50, but these holes can be alternatively configured without departing from the scope of the present invention.

The walls 54,56,58,64 and flanges 60,62 cooperatively define part of an internal space 66 of the modesty panel 14, with a forward access opening 68 that surrounds and permits access to the internal space 66. The shell also includes gussets 70 that interconnect the rear wall 54 and top and bottom walls 56,58. The shell further includes cable trays 72,74 and a support bracket 76 attached to the rear wall 54. The chassis shell is preferably made from sheet metal, such as carbon steel, but could be manufactured from other materials such as aluminum or plastics. The chassis 50 also includes an intermediate wall 78 attached to the rear wall 54 by the support bracket 76 as will be discussed further.

The chassis 50 is attached to the desk 12 by positioning the top wall 56 into contact with the lower surface, with the top wall 56 preferably extending along and substantially parallel to the front margin 40, and by extending threaded fasteners through the top wall 56 into the desktop 18. Thus, the chassis 50 is spaced below the desktop 18 so that the modesty panel 14, in the usual manner, hides part of the open space from view, particularly when viewed from the front of the desk 12. However, it is also consistent with the principles of the present invention where the chassis 50 is attached to the desk 12 in a different position, e.g., where the top wall 56 extends along and parallel to the one of the side margins 44.

The modesty panel 14 also includes an electrical power terminal 80 and an internet data terminal 82. The power terminal 80 includes four (4) conventional electrical power outlets and is attached to the rear wall 54 spaced above the cable tray 72. The data terminal 82 includes four (4) data jacks and is attached to the rear wall 54 below the cable tray 72 and between cable trays 74. The illustrated data jacks preferably comprise either an RJ 44 or an RJ11 socket, but could include another type of connector without departing from the scope of the present invention. The terminals 80,82 are served by power and data supply wires 84,86 that interconnect the terminals 80,82 with corresponding sources of electrical power (not shown) and data, e.g., a computer such as a computer server (not shown). The wires 84,86 also extend along the cable trays 72,74 and are operable to extend out of the hole formed when one of the punch-outs 64a is removed from the side wall 64. Thus, the chassis 50 and terminals 80,82 cooperatively provide a docking station for the laptop computer L.

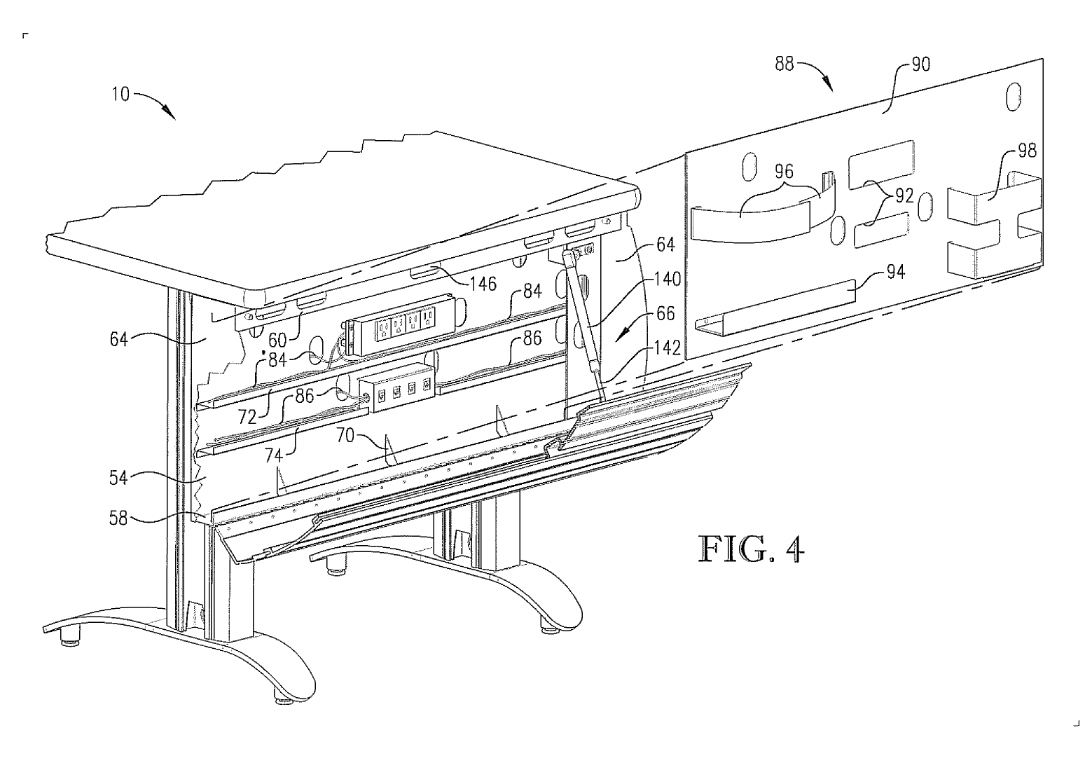

Turning to FIGS. 4 and 5, the chassis 50 also includes a removable partition 88 that is operable to receive the laptop computer L as will be discussed further. The partition 88 includes a substantially flat rectangular wall 90 that presents central openings 92 and a plurality of oval-shaped holes. Both the rectangular wall 90 and the intermediate wall 78 are preferably made of a layer of polycarbonate thermoplastic, such as Lexan®, but could be made of other materials such as aluminum or steel without departing from the scope of the present invention. Furthermore, the walls 78,90 are preferably translucent, but could also be opaque.

The partition 88 also includes a laptop container for holding the laptop computer L, with the laptop container including a laptop shelf 94 attached to the wall 90 on one side of the openings 92 and hook-and-loop holding straps 96 attached to the wall 90 in a position above the laptop shelf 94. The laptop computer L is supported vertically by the shelf 94, with the straps 96 surrounding the computer L to restrict lateral movement of the computer L. However, the laptop container could be alternatively constructed to secure the computer L during storage without departing from the scope of the present invention. The partition 88 further includes a peripheral container that comprises a unitary shelf 98 attached to the wall 90 on the other side of the openings 92. The shelf 98 is operable to contain multiple data storage disks D, such as a CD or DVD disk, and is further operable to store other computer peripherals (not shown), such as a mouse, a flash memory device, or a wireless communication card. It is also within the ambit of the present invention where the partition 88 includes other types of brackets or shelves for storing equipment or peripherals. Moreover, other parts of the modesty panel 14 could have brackets, shelves, or pockets mounted thereon and within the internal space for storing equipment or peripherals. For instance, the laptop container or the peripheral container could be mounted on and shiftable with the panel door 52.

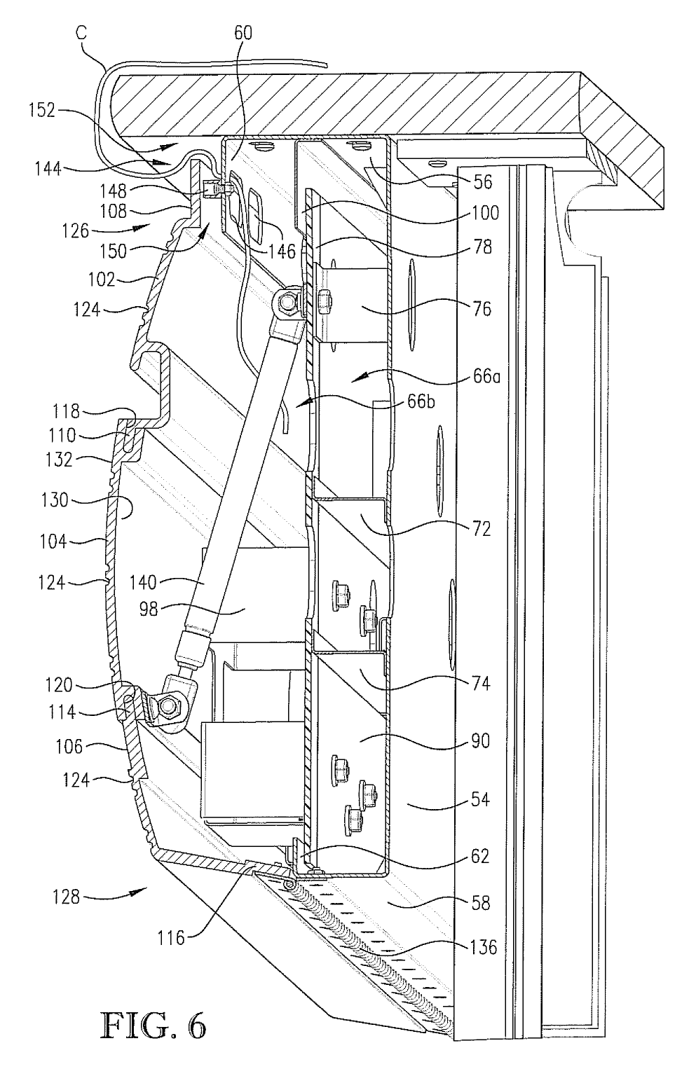

The partition 88 is shiftable into and out of an installed position where the partition 88 is received behind the bottom flange 62 and a retaining flange 100 attached to the top wall 56. The partition 88 rests on the bottom wall 58 and is spaced in front of the rear wall 54 and cable trays 72,74 so that the rear wall 54 and partition 88 cooperatively define a utility space 66a within the internal space 66. With the partition 88 installed, the central openings 92 are aligned with the terminals 80,82 to permit access to the power outlets and data jacks. The walls 78,90 are positioned alongside one another (see FIG. 6) to cooperatively span the opening defined between the retaining flange 100 and the bottom flange 62 and substantially cover the utility space 66a. However, it is also within the scope of the present invention where the walls 78,90 only partly span the opening between the flanges 62,100. While the partition 88 rests loosely within the chassis 50 in the installed position, the partition 88 could also be attached to components of the chassis 50 with conventional fasteners.

The partition 88 is removable from the installed position by first moving the partition 88 upwardly until a lower edge of the wall 90 is spaced above the bottom flange 62 and then shifting the lower edge forwardly to tilt the partition 88 out of the internal space 66. Similarly, the partition 88 is installed by moving an upper edge of the wall 90 into the internal space 66 and into a position behind the retaining flange 100. Then, the lower edge of the wall 90 can be shifted rearwardly to a position behind the bottom flange 62 so that the partition 88 can then be lowered into the installed position.

Turning to FIGS. 5 and 6, the panel door 52 comprises top, middle, and bottom door sections 102,104,106 that are rigidly interconnected to one another. The sections 102,104,106 each have a cross-sectional shape that is substantially constant along a longitudinal axis of the section. The top section 102 includes upper and lower flanges 108,110 and a channel portion 112 spaced between the flanges 108,110 that serves as a handle for the panel door 52. The bottom section 106 has walls that converge to generally form an oblique angle therebetween, with one wall including an upper flange 114 and the other wall including a lower flange 116. The middle section 104 presents upper and lower longitudinal slots 118,120 that receive the flanges 110,114, respectively, with set screws 122 securing the flanges 110,114 within the slots 118,120. The sections 102,104,106 also present longitudinal grooves 124. The illustrated sections 102,104,106 are preferably made from extruded aluminum, but could be made from other materials such as steel or plastics without departing from the scope of the present invention.

The panel door 52 presents top and bottom margins 126,128, a generally concave inner surface 130, and a generally convex outer surface 132 that is corrugated by the grooves 124, with the surfaces 130,132 extending between the margins 126,128. The sections 102,104,106 are preferably manufactured and interconnected so that the outer surface 132 is solid and continuous from the top margin 126 to the bottom margin 128. However, it is also within the scope of the present invention where the panel door 52 presents one or more openings in the outer surface 132 between the margins 126,128 to permit visual inspection of the internal space 66 when the panel door 52 is closed. Also, the illustrated panel door 52 is preferably opaque, but could also be translucent or transparent. The panel door 52 further includes a lock 134 that is preferably operable to be locked by a key (not shown) and is attached to the upper flange 108 of the top door section 102.

The illustrated panel door 52 is preferably swingably attached to the chassis 50 by interconnecting the bottom wall 58 of the chassis 50 and the bottom door section 106 with a hinge 136. However, it is also within the ambit of the present invention where the panel door 52 is pivotally attached to the chassis 50 along one of the side walls 64 or along the top wall 56. Furthermore, the panel door 52 could be attached to the chassis 50 with a mechanism other than a hinge, e.g., where the door 52 is slidably attached to the chassis 50. As will be discussed further, the panel door 52 is swingable between a closed position where the panel door 52 substantially covers the access opening 68 to enclose the internal space 66 and an open position where the panel door 52 is positioned below the access opening 68.

The modesty panel 14 also includes a piston-and-cylinder damper 138, with a cylinder 140 and a piston 142 slidably received in the cylinder 140 and slidable from a retracted position (see FIG. 5) to an outermost extended position (see FIG. 4). The cylinder 140 has an end fixed to the support bracket 74, and the piston 142 has a movable end attached to the panel door 52. In the usual manner, the moveable end is slidable toward or away from the fixed end. Furthermore, the damper 138 provides a force that acts against sliding movement of the moveable end relative to the fixed end. For instance, a force applied to the moveable end to slide the moveable end toward the fixed end causes the damper 138 to exert a damping force against the applied force, where the damping force is smaller than the applied force. Thus, as the panel door 52 is swung open from the closed position by an applied opening force, the damper 138 acts against the opening force to slow the opening movement. Similarly, as the panel door 52 is swung closed into the closed position by an applied closing force, the damper 138 acts against the closing force to slow the closing movement. Furthermore, the extended position of the damper 138 restricts pivotal movement of the panel door 52 beyond the open position.

In the closed position, the panel door 52 extends along an outermost edge of the side walls 64 and along the flanges 60,62. The lock 134 extends through the top flange 60 to selectively interlock the upper flange 108 and the top flange 60. The chassis 50 and panel door 52 cooperatively define a storage space 66b within the internal space 66, with the storage space 66b being between the partition 88 and the panel door 52. Furthermore, the walls 78,90 cooperatively separate the utility space 66a from the storage space 66b. However, it is also within the scope of the present invention where the spaces 66a,66b are not separated by a wall or other structure. While the panel door 52 and the partition 88 preferably serve as the only shiftable access doors of the modesty panel 14, it is also within the ambit of the present invention where another shiftable door is used. For instance, a door could be attached to the rear wall 54 to cover a door opening defined in the rear wall 54 and permit selective access through the door opening to the utility space 66a from the rear of the modesty panel 14.

When closed, the panel door 52 covers the access opening 68 and thereby restricts removal of the laptop computer L from the storage space 66b. In this manner, the modesty panel 14 provides secure storage of the laptop computer L and other stored components. However, the illustrated chassis 50 and panel door 52 cooperatively define a passage 144 that permits laptop cables C to extend from the laptop computer L and into the storage space 66b when the panel door 52 is in the closed position. In particular, the top flange 60 presents a plurality of holes 146 that are spaced adjacent to the upper flange 108. The chassis 50 includes a pair of bumpers 148 attached to the top flange 60 and extending forwardly therefrom to hold the upper flange 108 in a position spaced forwardly from the top flange 60, with a gap 150 therebetween that permits access to the holes 146. In other words, the holes 146 and the gap 150 cooperatively form the illustrated passage 144, which permits the laptop cables C to extend over the upper flange 108 and downwardly through the holes 146 into the storage space 66b without the cables C being damaged due to excessive bending or pinching. A gap 152 is also provided between the upper flange 108 and the desktop 18 that allows the cables C to extend through the passage 144. However, it is also within the ambit of the present invention where the passage 144 is formed in another portion of the of the modesty panel 14. For instance, the passage 144 could be presented by one of the side walls 64 or by the panel door 52.

Thus, the modesty panel 14 provides a docking station when the panel door 52 is closed and the laptop computer L is in use on the desktop 18. However, the configuration of the passage 144 substantially restricts components within the storage space 66b from being removed while the panel door 52 is in the closed position.

In operation, the laptop computer L is stored in the modesty panel 14 in a storage condition by opening the panel door 52 and securing the laptop computer L by placing it on the shelf 94 and securing the straps 96 around the computer L. Then, the panel door 52 is swung into the closed position, with the lock 134 being locked to provide the storage condition. The modesty panel 14 is operable to dock with and support the laptop computer L for use in an operating condition by opening the panel door 52 and removing the laptop computer L from the storage space 66b, with the laptop computer L being supported on the desktop 18. Then, the laptop cables C are attached to the laptop computer L, fed through one of the holes 146, and then connected to corresponding power outlet and data jack. The panel door 52 is then returned to the closed position, with the modesty panel 14 in the operating condition, without pinching or harmfully bending the cables C.

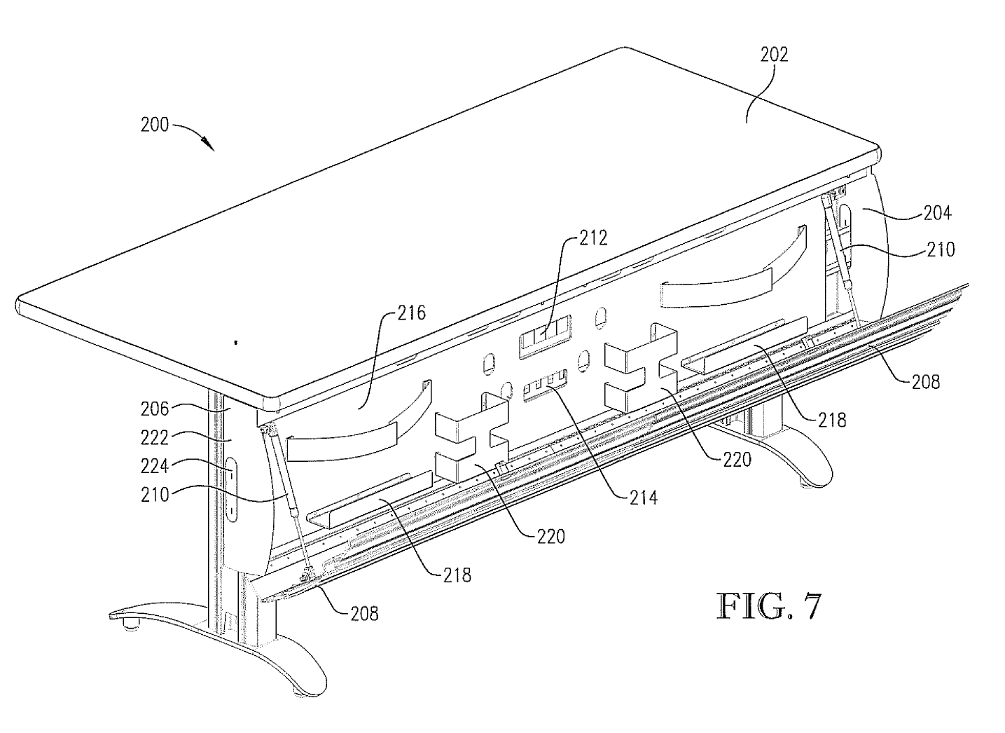

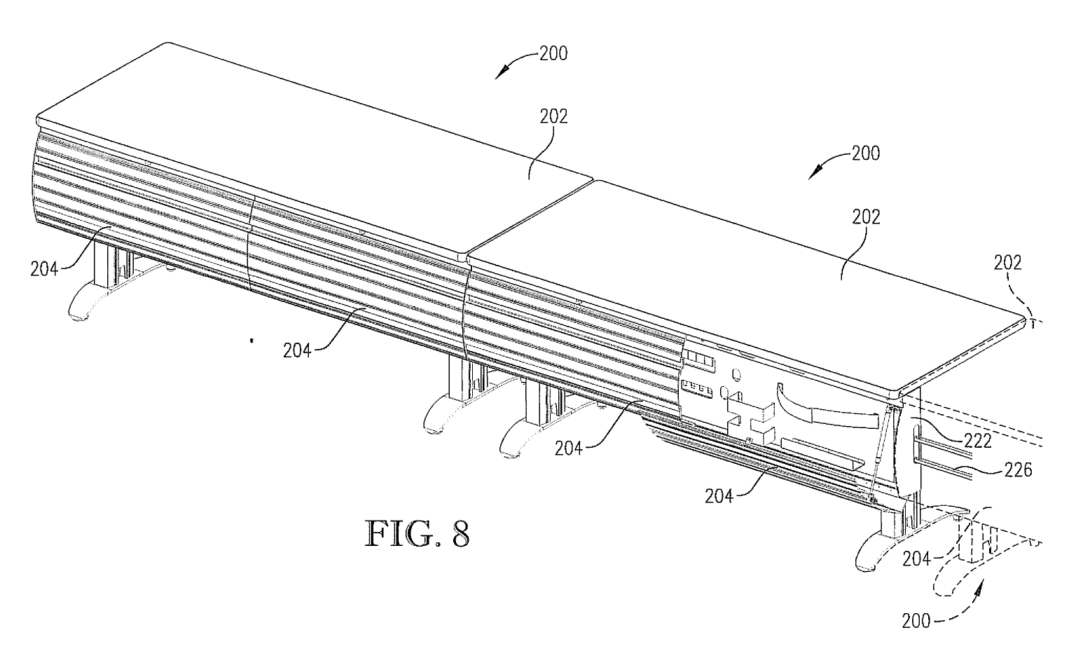

Turning to FIGS. 7 and 8, an alternative workstation 200 is constructed in accordance with a second embodiment of the present invention. For the sake of brevity, the remaining description will focus primarily on the differences of this alternative embodiment from the embodiment described above. The alternative workstation 200 includes an alternative desk 202 and an alternative modesty panel 204. The alternative modesty panel 204 includes a chassis 206, a pair of panel doors 208, and a pair of dampers 210, with the chassis 206 and panel doors cooperatively defining an internal space. The chassis 206 broadly includes power and data terminals 212,214 and a partition 216 that are positioned within the internal space. The partition 216 includes a pair of laptop containers 218 and a pair of peripheral containers 220. The modesty panel 204 is preferably configured so that both sets of containers 218,220 have access to the terminals 212,214. Furthermore, one set of containers 218,220 is positioned behind one panel door 208 and another set of containers 218,220 is positioned behind another panel door 208. In this manner, each panel door 208 permits access to a corresponding set of containers 218,220 and the laptop computer and peripherals contained therein. The illustrated panel doors 208 are also independently swingable and permit selective access to either or both sets of containers 218,220.

As shown in FIG. 8, multiple workstations 200 can be arranged side-by-side and operably coupled to one another. In particular, a pair of adjacent workstations 200 can be aligned with side walls 222 positioned adjacent to one another. A punch-out section 224 of each side wall 222 can be removed to present openings in the side walls 222 that communicate with each other and permit transmission wires 226 to extend through the openings. Thus, the transmission wires 226 can extend from one set of terminals 212,214 in one workstation 200 through the openings to another set of terminals 212,214 in an adjacent workstation 200 and thereby operably interconnect the terminals 212,214 of the adjacent workstations 200. In this manner, adjacent workstations 200 serve to substantially enclose and secure the transmission wires 226 that interconnect the adjacent workstations 200.

The preferred forms of the invention described above are to be used as illustration only, and should not be utilized in a limiting sense in interpreting the scope of the present invention. Obvious modifications to the exemplary embodiments, as hereinabove set forth, could be readily made by those skilled in the art without departing from the spirit of the present invention.

The inventors hereby state their intent to rely on the Doctrine of Equivalents to determine and assess the reasonably fair scope of the present invention as pertains to any apparatus not materially departing from but outside the literal scope of the invention as set forth in the following claims.

What is claimed is:

1. A workstation modesty panel configured to be attached to a desk below a desktop, said workstation modesty panel operable to store a laptop computer in a storage condition and operable to be coupled to the laptop computer in an operating condition where the desktop supports the laptop computer for use, said workstation modesty panel comprising:
a chassis presenting a laptop access opening through which the laptop computer is configured to pass when placed in or removed from storage;
a panel door shiftably attached to the chassis and shiftable into and out of a covering position where the panel door substantially covers the laptop access opening,
said chassis and panel door cooperatively defining a storage space operable to receive the laptop computer in the storage condition,
said panel door being in the covering position when the workstation modesty panel is in the storage condition, with the chassis and panel door operable to cooperatively restrict removal of the laptop computer from the storage space,
said panel door being shiftable out of the covering position to permit removal of the laptop computer from the storage space via the laptop access opening; and
an electrical terminal mounted within the storage space and configured to be operably coupled to the laptop computer by a transmission wire,
at least one of said chassis and said panel door presenting a wire passage adjacent the laptop access opening that permits the transmission wire to extend from the terminal to the laptop computer in the operating condition, when the panel door is in the covering position.

2. The workstation modesty panel as claimed in claim 1,
said chassis including an upright wall,
said chassis including a docking shelf mounted on the upright wall and positioned between the upright wall and the panel door,
said docking shelf operable to hold the stored laptop computer in the storage space.

3. The workstation modesty panel as claimed in claim 2,
said upright wall being removably attached to a remainder of the chassis.

4. The workstation modesty panel as claimed in claim 2,
said chassis including another shelf mounted on the wall adjacent the docking shelf and operable to support peripheral components of the laptop computer.

5. The workstation modesty panel as claimed in claim 1,
said chassis including a first upright wall, with the electrical terminal being mounted on the first upright wall,
said chassis including a second upright wall spaced from the first upright wall to separate the storage space from a utility space defined between the walls,
said electrical terminal being positioned in the utility space, with the second upright wall substantially covering the utility space.

6. The workstation modesty panel as claimed in claim 5,
said chassis including a docking shelf mounted on the second upright wall and positioned between the second upright wall and the panel door,
said docking shelf operable to hold the stored laptop computer in the storage space.

7. The workstation modesty panel as claimed in claim 6,
said chassis including another shelf mounted on the second upright wall adjacent the docking shelf and operable to support peripheral components of the laptop computer.

8. The workstation modesty panel as claimed in claim 5,
said second upright wall presenting an access opening, with the electrical terminal being aligned with the access opening.

9. The workstation modesty panel as claimed in claim 5,
said chassis including a cable tray mounted within the utility space to the first upright wall adjacent the electrical terminal and operable to support a wire extending through the utility space from the electrical terminal.

10. The workstation modesty panel as claimed in claim 9,
said chassis including a side wall attached to the first upright wall,
said side wall including a removable punch-out section positioned adjacent to an end of the cable tray,
said punch-out section being removable so that the side wall defines an opening configured to receive the wire and permit the wire to extend from the cable tray and out of the chassis.

11. The workstation modesty panel as claimed in claim 5,
said second upright wall being removably attached to a remainder of the chassis to selectively permit access to the utility space from the storage space.

12. The workstation modesty panel as claimed in claim 1,
said panel door comprising a swingable door presenting upper and lower door margins,
said panel door being swingably mounted along the lower door margin to a lowermost section of the chassis,
said panel door including a lock mechanism positioned adjacent the upper door margin,
said lock mechanism engaging an uppermost section of the chassis when the panel door is in the covering position to hold the panel door closed.

13. The workstation modesty panel as claimed in claim 12,
said wire passage extending along the upper door margin.

14. The workstation modesty panel as claimed in claim 12; and
a damper that interconnects the swingable panel door and the chassis to provide a damping force against the swingable panel door in a direction opposite swinging door movement.

15. The workstation modesty panel as claimed in claim 1,
said electrical terminal being a power terminal and/or a data terminal.

16. The workstation modesty panel as claimed in claim 1,
said panel door presenting oppositely spaced door margins,
said door presenting a solid outer surface that extends continuously from one door margin to the other.

17. The workstation modesty panel as claimed in claim 1,
said panel door comprising a plurality of side-by-side panel door sections, with each panel door section being independently shiftable relative one another,
said chassis including an upright wall,
said chassis including a plurality of docking shelves mounted on the upright wall, with each of the docking shelves positioned between the upright wall and a corresponding panel door section,
each of said docking shelves operable to hold a respective one of the stored laptop computers in the storage space.

18. A laptop workstation configured to store and operably support a laptop computer, said laptop workstation comprising:
a desk including a desktop that presents proximal and distal margins and a laterally-extending work surface extending between the margins,
said desk defining an open space below the desktop that is operable to receive an operator's legs extending under the proximal margin from a location outside the open space,
said desktop presenting a laterally-extending work surface configured to support the laptop computer thereon for use in an operating condition; and
a panel assembly operable to store the laptop computer in a storage condition and operable to be coupled to the laptop computer in the operating condition,
said panel assembly attached to the desk and extending along the distal margin below the desktop to at least partly conceal the open space and thereby provide a modesty panel,
said panel assembly including a chassis presenting a laptop access opening through which the laptop computer is configured to pass when placed in or removed from storage,
said panel assembly including a panel door shiftably attached to the chassis and shiftable into and out of a covering position where the panel door substantially covers the laptop access opening,
said chassis and panel door cooperatively defining a storage space configured to store the laptop computer in the storage condition,
said panel door being in the covering position when the panel assembly is in the storage condition, with the chassis and panel door operable to cooperatively restrict removal of the laptop computer from the storage space,
said panel door being shiftable out of the covering position to permit removal of the laptop computer from the storage space via the laptop access opening,
said panel assembly including an electrical terminal mounted within the storage space and configured to be operably coupled to the laptop computer by a transmission wire,
at least one of said chassis and said panel door presenting a wire passage adjacent the laptop access opening that permits the transmission wire to extend from the terminal to the laptop computer in the operating condition, when the panel door is in the covering position.

19. The laptop workstation as claimed in claim 18,
said chassis including an upright wall,
said chassis including a docking shelf mounted on the upright wall and positioned between the upright wall and the panel door,
said docking shelf operable to hold the stored laptop computer in the storage space.

20. The laptop workstation as claimed in claim 19,
said upright wall being removably attached to a remainder of the chassis.

21. The laptop workstation as claimed in claim 19,
said chassis including another shelf mounted on the wall adjacent the docking shelf and operable to support peripheral components of the laptop computer.

22. The laptop workstation as claimed in claim 18,
said chassis including a first upright wall, with the electrical terminal being mounted on the first upright wall,
said chassis including a second upright wall spaced from the first upright wall to separate the storage space from a utility space defined between the walls,
said electrical terminal being positioned in the utility space, with the second upright wall substantially covering the utility space.

23. The laptop workstation as claimed in claim 22,
said chassis including a docking shelf mounted on the second upright wall and positioned between the second upright wall and the panel door,
said docking shelf operable to hold the stored laptop computer in the storage space.

24. The laptop workstation as claimed in claim 23,
said chassis including another shelf mounted on the second upright wall adjacent the docking shelf and operable to support peripheral components of the laptop computer.

25. The laptop workstation as claimed in claim 22,
said second upright wall presenting an access opening, with the electrical terminal being aligned with the access opening.

26. The laptop workstation as claimed in claim 22,
said chassis including a cable tray mounted within the utility space to the first upright wall adjacent the electrical terminal and operable to support a wire extending through the utility space from the electrical terminal.

27. The laptop workstation as claimed in claim 26,
said chassis including a side wall attached to the first upright wall,
said side wall including a removable punch-out section positioned adjacent to an end of the cable tray,
said punch-out section being removable so that the side wall defines an opening configured to receive the wire and permit the wire to extend from the cable tray and out of the chassis.

28. The laptop workstation as claimed in claim 22,
said second upright wall being removably attached to a remainder of the chassis to selectively permit access to the utility space from the storage space.

29. The laptop workstation as claimed in claim 18,
said panel door comprising a swingable door presenting upper and lower door margins,
said panel door being swingably mounted along the lower door margin to a lowermost section of the chassis,
said panel door including a lock mechanism positioned adjacent the upper door margin,
said lock mechanism engaging an uppermost section of the chassis when the panel door is in the covering position to hold the panel door closed.

30. The laptop workstation as claimed in claim 29,
said wire passage extending along the upper door margin.

31. The laptop workstation as claimed in claim 29,
said panel assembly including a damper that interconnects the swingable panel door and the chassis to provide a damping force against the swingable panel door in a direction opposite swinging door movement.

32. The laptop workstation as claimed in claim 18,
said electrical terminal being a power terminal and/or a data terminal.

33. The laptop workstation as claimed in claim 18,
said panel door presenting oppositely spaced door margins,
said door presenting a solid outer surface that extends continuously from one door margin to the other.

34. The laptop workstation as claimed in claim 18,
said panel door comprising a plurality of side-by-side panel door sections, with each panel door section being independently shiftable relative one another,
said chassis including an upright wall,
said chassis including a plurality of docking shelves mounted on the upright wall, with each of the docking shelves positioned between the upright wall and a corresponding panel door section,
each of said docking shelves operable to hold a respective one of the stored laptop computers in the storage space.

35. The laptop workstation as claimed in claim 18,
said distal margin being positioned opposite the proximal margin.

36. The laptop workstation as claimed in claim 35,
said wire passage extending along and being positioned adjacent the distal margin to permit the transmission wire to extend over the distal margin in the operating condition.
